(19) United States
(12) Patent Application Publication
(10) Pub. No.: US 2016/0306014 A1
(43) Pub. Date: Oct. 20, 2016

(54) APPARATUS AND METHOD FOR DETERMINING CONNECTION STATUS OF BUSBAR

(71) Applicant: Samsung Electronics Co., Ltd., Suwon-si (KR)

(72) Inventor: Jin Yong JEON, Yongin-si (KR)

(73) Assignee: Samsung Electronics Co., Ltd., Suwon-si (KR)

(21) Appl. No.: 15/130,260

(22) Filed: Apr. 15, 2016

(30) Foreign Application Priority Data
Apr. 15, 2015 (KR) 10-2015-0053383

(51) Int. Cl. G01R 31/36; G08B 21/18; G01R 31/04

(52) U.S. Cl. CPC G01R 31/3682; G01R 31/3696; G01R 31/04; G08B 21/182

(57) ABSTRACT

An apparatus for determining connections status of a busbar includes a voltage measurer configured to measure a voltage across two ends of the busbar used to connect a first battery module and a second battery module in series, and a status determiner configured to determine connection status of the busbar according to the voltage.

### CROSS-REFERENCE TO RELATED APPLICATION(S)

This application claims the benefit under 35 USC 119(a) of Korean Patent Application No. 10-2015-0053383, filed on Apr. 15, 2015, in the Korean Intellectual Property Office, the entire disclosure of which is incorporated herein by reference for all purposes.

### BACKGROUND

1. Field

The following description relates to an apparatus and method for determining connection status of a busbar used in a battery pack.

2. Description of Related Art

Unlike primary batteries, secondary batteries are generally rechargeable and are used as energy sources of small mobile devices, such as cellular phones, laptop computers, and camcorders, or energy sources of medium and large devices, such as electric cars, hybrid electric cars, electric bicycles, Energy Storage Systems (ESS), Uninterruptible Power Supply (UPS), robots, and artificial satellites.

Among the devices, the small mobile device uses a small number of battery cells, whereas the medium or large device, such as electric cars, hybrid electric cars, electric bicycles, Energy Storage Systems (ESS), Uninterruptible Power Supply (UPS), robots, and artificial satellites, which requires high power and high capacity, uses a battery pack having a plurality of battery cells that are electrically connected with each other.

Generally, battery cells are connected in series to form a battery module. A plurality of battery modules are connected through a connecting member, such as a busbar, to form a battery pack, thereby providing higher power and capacity.

However, when a battery pack is used in an environment where there is a lot of vibration, such as when mounted on a vehicle, coupling screws of a busbar that connect the battery modules may loosen. In this case, contact resistance may be increased by the loosened screws, thereby generating electric spark, which may cause failures or fire in battery cells.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, an apparatus for determining connections status of a busbar includes a voltage measurer configured to measure a voltage across two ends of the busbar used to connect a first battery module and a second battery module in series, and a status determiner configured to determine connection status of the busbar according to the voltage.

The voltage measurer may be configured to measure the voltage by measuring the voltage between one end of the first battery module connected to the busbar and one end of the second battery module connected to the busbar.

The voltage measurer may be configured to measure a first voltage across two ends of a battery cell of the first battery module connected to the busbar, measure a second voltage between one end of the second battery module connected to the busbar and one end of the first battery cell farther from the busbar than another end of the first battery cell, and calculate the voltage across two ends of the busbar based on the measured first voltage and the measured second voltage.

The status determiner may be configured to compare the voltage across two ends of the busbar with a threshold voltage, and determine that connection status of the busbar is a risk status in response to the comparing indicating that the voltage across two ends of the busbar meets the threshold voltage. In response to the voltage accross two ends of the busbar being greater than the predetermined threshold voltage, the status determiner may be configured to determine whether the voltage across two ends of the busbar is determined to meet the threshold voltage a number of times that meets a second threshold value, and in response to the number of times meeting the second threshold value, the status determiner is configured to determine the connection status of the busbar to be a risk status.

The apparatus may further include an alarm component configured to output an acoustic alarm, a visual alarm, or a tactile alarm, or any combination thereof, in response to the determiner determining that the connection status of the busbar as in a risk status.

In another general aspect, a method of determining connection status of a busbar, the method includes measuring a voltage across two ends of the busbar connecting a first battery module and a second battery module in series, and determining a connection status of the busbar based on the voltage.

The measuring of the voltage may include measuring the voltage across two ends of the busbar by measuring the voltage between one end of the first battery module connected to the busbar and one end of the second battery module connected to the busbar.

The measuring of the voltage may include measuring a first voltage across two ends of a battery cell, of the first battery module, connected to the busbar, measuring a second voltage between one end of the second battery module connected to the busbar one end of the first battery cell distal to the busbar, and calculating the voltage across two ends of the busbar according to the measured first voltage and the measured second voltage.

Determining of the connection status of the busbar may include comparing the voltage across two ends of the busbar with a predetermined threshold voltage, and determining that connection status of the busbar is a risk status in response to the comparing indicating that the voltage across two ends of the busbar meets the threshold voltage.

In response to the voltage across two ends of the busbar being meeting the threshold voltage, the determining of the connection status of the busbar may further include comparing a number of times the voltage across two ends of the busbar is greater than the threshold voltage with a second threshold value, and in response to the number of times the voltage applied on both ends of the busbar being greater than the threshold voltage being above the second threshold value, determining the connection status of the busbar to be the risk status.

The method may further include outputting an acoustic alarm, a visual alarm, or a tactile alarm, or any combination thereof, in response to the risk status.

Other features and aspects will be apparent from the following detailed description, the drawings, and the claims.

### BRIEF DESCRIPTION OF THE DRAWINGS

FIG. 1 is a block diagram illustrating an example of an apparatus for determining connection status of a busbar.

FIG. 2 is a detailed diagram illustrating an example voltage measurer.

FIGS. 3A through 3C are diagrams illustrating an example of determining connection status of a busbar by indirectly measuring voltage applied on ends of a busbar.

FIG. 4 is a diagram illustrating an example of a criterion for determining connection status of a busbar based on voltage applied on both ends of a busbar.

FIG. 5 is a block diagram illustrating an example of an apparatus for determining connection status of a busbar.

FIG. 6 is a flowchart illustrating an example of a method of determining connection status of a busbar.

FIG. 7 is a flowchart illustrating an example of a method of determining connection status of a busbar.

FIG. 8 is a flowchart illustrating an example of a method of determining connection status of a busbar.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, after an understanding of the present disclosure, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order, after an understanding of the present disclosure. Also, descriptions of functions and constructions that are understood from previous discussions may be omitted from subsequent discussions for increased clarity and conciseness.

The features described herein may be embodied in different forms, and are not to be construed as being limited to the examples described herein. Rather, the examples described herein have been provided so that this disclosure will be thorough and aspects understood, and will convey a full scope of the disclosure to one of ordinary skill in the art.

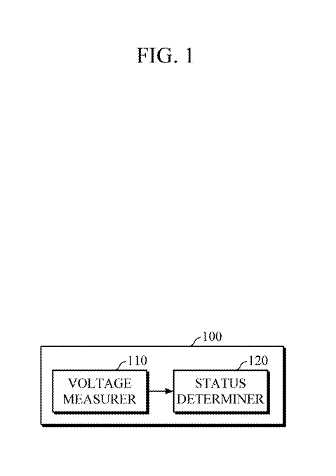

FIG. 1 is a block diagram illustrating an example of an apparatus for determining connection status of a busbar. Referring to FIG. 1, the apparatus 100 for determining connection status of a busbar includes a voltage measurer 110 and a status determiner 120, for example. The voltage measurer 110 measures voltage applied on both ends of a busbar used to connect two battery modules (a first battery module and a second battery module) in series.

Generally, the busbar is connected to battery modules through one or more connecting members. For example, the first battery module and the busbar are connected through a first connecting member, and the second battery module and the busbar are connected through a second connecting member. In this case, the connecting members (the first connecting member and the second connecting member) may include screws, pins, bolts and nuts, for example, though embodiments are not limited thereto.

Accordingly, the voltage applied on both ends of the busbar may be influenced by internal resistance of the busbar, internal resistance of the connecting members (the first connecting member and the second connecting member), and a virtual resistance generated between the busbar and the connecting members according to a degree of connection between the connecting members and the busbar.

In an embodiment, the voltage measurer 110 directly measures voltage applied on both ends of the busbar, for example two ends of the busbar. For example, the voltage measurer 110 directly measures voltage applied on both ends of the busbar by measuring voltage applied between one end of the first battery module that is connected to the busbar and one end of the second battery module that is connected to the busbar.

In another embodiment, the voltage measurer 110 indirectly measures a voltage across two ends of the busbar. For example, the voltage measurer 110 indirectly measures a voltage across ends of the busbar by measuring a first voltage across two ends of a first battery cell that is connected to the busbar among a plurality of battery cells of the first battery module and a second voltage between one end of the first battery cell that is farther from the busbar and an end of the second battery module that is connected to the busbar. The voltage measurer 110 then calculates the voltage across two ends of the busbar based on the first voltage and the second voltage.

The status determiner 120 determines connection status of the busbar with the first battery module and the second battery module based on the voltage across both ends of the busbar and measured by the voltage measurer 110.

By tightening the first connecting member and the second connecting member to fixedly or firmly connect the first battery module with the busbar and the second battery module with the busbar, a first virtual resistance generated between the busbar and the first connecting member according to a degree of connection of the first connecting member and the busbar should be zero or almost zero, and a second virtual resistance generated between the busbar and the second connecting member according to a degree of connection of the second connecting member and the busbar should be zero or almost zero.

By contrast, in the case where the connection of the first battery module with the busbar or the connection of the second battery module with the busbar is loose or loosened by disconnection of the first connecting member or the second connecting member, the first virtual resistance or the second virtual resistance will be greater than zero.

Accordingly, in the case where the first connecting member or the second connecting member is loose or loosened after the first connecting member and the second connecting member were previously tightened, the first virtual resistance or the second virtual resistance is increased, thereby increasing voltage across two ends of the busbar.

In an embodiment, the status determiner 120 compares voltage across both ends of the busbar with a predetermined threshold voltage. In response to the voltage across both ends of the busbar being greater than the predetermined threshold voltage, the status determiner 120 determines that there is a risk of disconnection of the first connecting member or the second connecting member, i.e., connection status of the busbar is unstable (hereinafter referred to as a “risk status”).

Many causes may result in errors when measuring a voltage across two ends of the busbar. That is, if a voltage greater than the predetermined threshold voltage is measured across both ends of the busbar due to an error in voltage measurement, the status determiner 120 may determine that connection status is a risk status, although in reality the risk status is not the case.

In an embodiment, in order to prevent such error, the status determiner 120 determines that connection status is a risk status in response to the voltage meeting, e.g. being greater than, the predetermined threshold voltage at least a set number of times, i.e. with the number of times meeting a predetermined threshold value.

Further, the risk status may be divided into a first-level risk status and a second-level risk status. In this example, the status determiner 120 compares a voltage across both ends of the busbar with a predetermined first threshold voltage. In response to the voltage across both ends of the busbar meeting the predetermined first threshold voltage, the status determiner 120 determines that connection status is the first-level risk status. In addition, the status determiner 120 compares a voltage across both ends of the busbar with a predetermined second threshold voltage, which is greater than the first threshold voltage. In response to the voltage across both ends of the busbar being greater than the predetermined second threshold voltage, the status determiner 120 determines that connection status is a risk status.

In this example, the higher the level of a risk status (e.g. second level risk status versus a first level risk status), the looser the connecting members may be. However, the risk status is not limited to two levels, and may be divided into three or more levels according to usage and performance of a system, and depending on an embodiment.

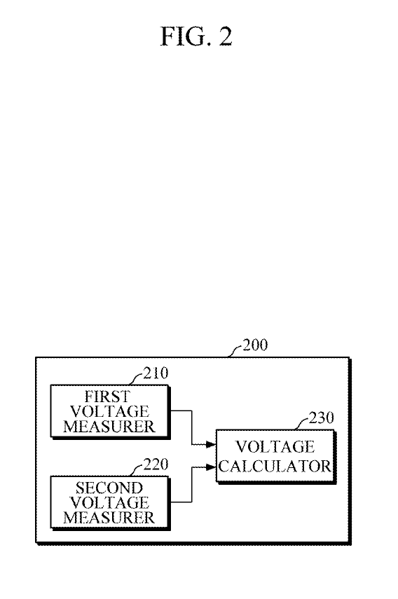

FIG. 2 is a detailed diagram illustrating an example voltage measurer, such as the voltage measurer 110 illustrated in FIG. 1, as only an example. The voltage measurer 110 may be applied to indirectly measure a voltage across ends of the busbar. Referring to FIG. 2, a voltage measurer 200 includes a first voltage measurer 210, a second voltage measurer 220, and a voltage calculator 230.

The first voltage measurer 210 may measure a first voltage, which is a voltage across two ends of a battery cell (a first battery cell) that is connected to a busbar among a plurality of battery cells in a first battery module. The second voltage measurer 220 may measure a second voltage, which is a voltage across one end of the first battery cell distal to the busbar and one end of a second battery module that is connected to the busbar.

The voltage calculator 230 calculates a voltage across two ends of the busbar based on the first voltage and the second voltage. For example, the voltage calculator 230 may calculate a voltage across two ends of the busbar by subtracting the first voltage from the second voltage.

Noting that alternatives are available, in an embodiment, the first voltage measurer 210 and the second voltage measurer 220 may be a chipset for measuring voltage of a plurality of battery cells, and the voltage calculator 230 and the status determiner 120 may be a Micro Controller Unit (MCU) or processor. In this case, an isolator that electrically isolates the chipset and the MCU may be connected between the chipset and the MCU to provide a measured battery cell voltage to the MCU.

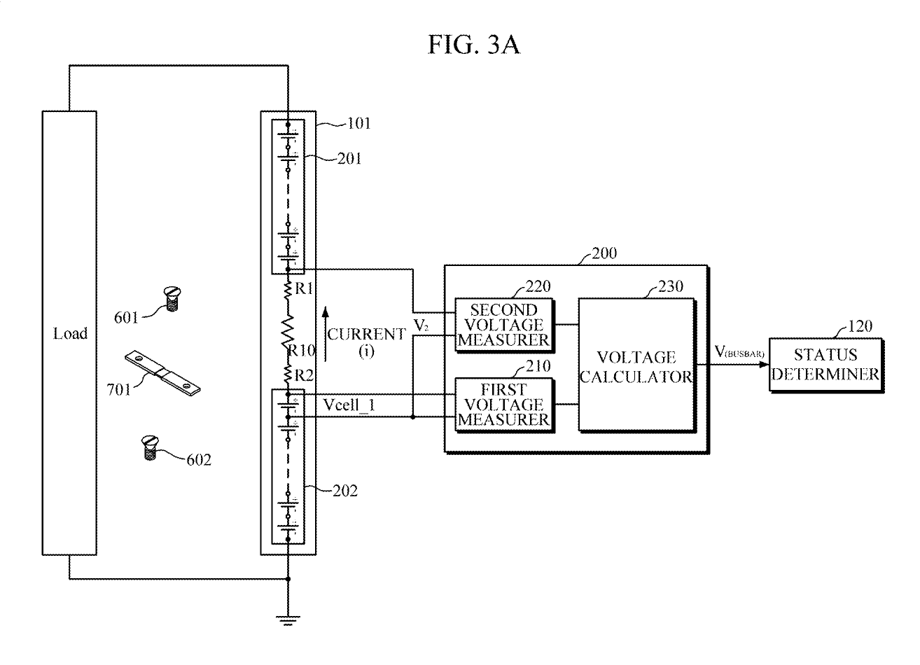

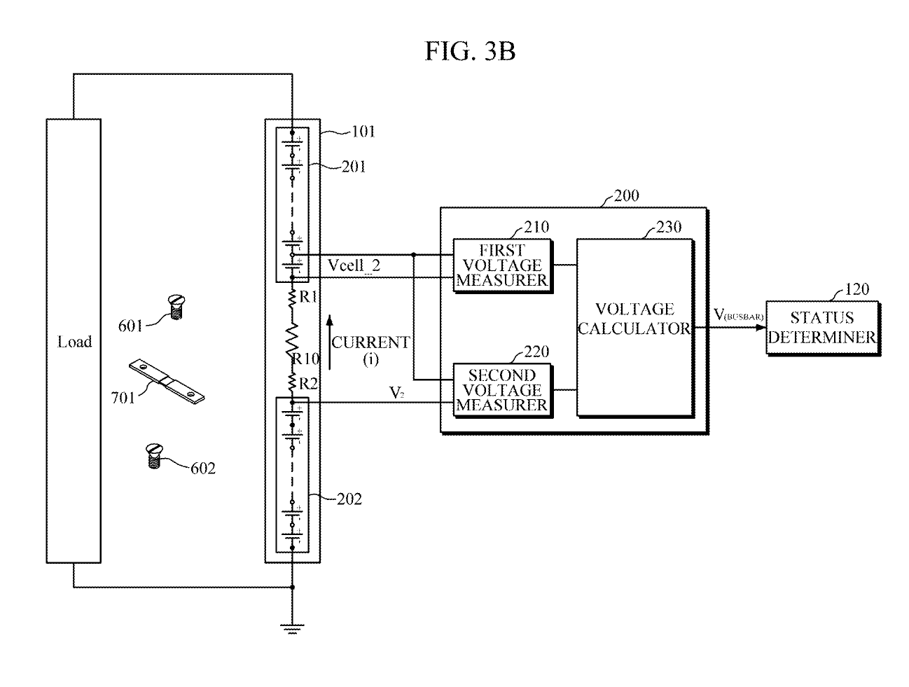

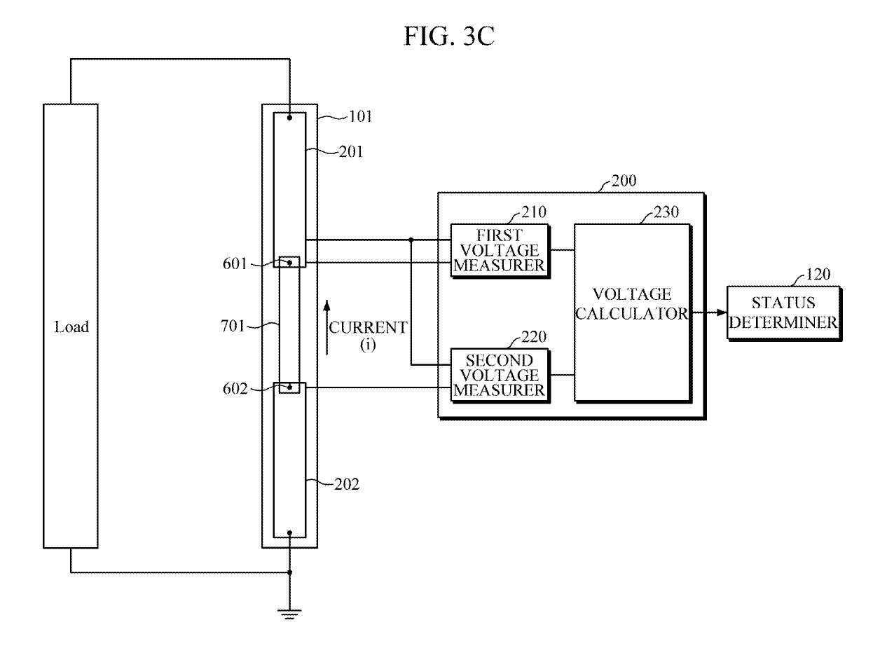

FIGS. 3A through 3C are diagrams illustrating an example of determining connection status of a busbar by indirectly measuring voltage applied on both ends of a busbar.

In FIGS. 3A and 3B, a battery pack 101 includes a plurality of battery modules 201 and 202 that are connected in series, and the battery modules 201 and 202 include a plurality of battery cells 501 and 502 that are connected in series. In FIGS. 3A and 3B, the illustrated connecting member 601, busbar 701, and connecting member 602 are separately illustrated as a convenience, though they in actuality are physically sequentially arranged between, and electrically connected to, the battery modules 201 and 202, such as in FIG. 3C. For example, resistance R1 refers to resistance at a connected portion between the battery module 201 and the busbar 701, i.e., an internal resistance of a connecting member 601 and a virtual resistance generated between the busbar 701 and the connecting member 601 depending on a degree of connection of the connecting member 601 and the busbar 701. Likewise, resistance R10 refers to an internal resistance of the busbar 701, and resistance R2 refers to resistance at a connected portion between the battery module 202 and the busbar 701, i.e., an internal resistance of a connecting member 602 and a virtual resistance generated between the busbar 701 and the connecting member 602 depending on a degree of connection of the connecting member 602 and the busbar 701.

Referring to FIG. 3A, the first voltage measurer 210 measures a first voltage (Vcell_1) across two ends of the illustrated battery cell 501. The second voltage measurer 220 measures a second voltage (V2) between one end of the battery cell 501 that is farther from the busbar 701 and an end of the battery module 201 that is connected to the busbar 701. In this case, with a current flowing across the busbar 701 being i, the second voltage (V2) measured by the second voltage measurer 220 is V2=Vcell_1+(R1+R2+R10)*i.

The voltage calculator 230 calculates a voltage (Vbusbar) across two ends of the busbar based on the first voltage (Vcell_1) and the second voltage (V2). In this case, the voltage (Vbusbar) calculated by the voltage calculator 230 is Vbusbar=V2−Vcell_1=(R1+R2+R10)*i.

In the case where the connecting member 601 is loose or loosened, a resistance value of the resistance R1 will be increased or greater than zero, and in the case where the connecting member 602 is loose, a resistance value of the resistance R2 will be increased or greater than zero. Accordingly, in the case where the connecting member 601 or the connecting member 602 is loose or loosened, voltage (Vbusbar) across both ends of the busbar will be greater than when the connecting members 601 and 602 are respectively tight or fixed with the respective connected battery modules.

Accordingly, the status determiner 120 determines that connection status is a risk status in response to the voltage (Vbusbar) applied on both ends of the busbar being greater than a predetermined threshold voltage (Vth).

Upon comparison with FIG. 3A, FIG. 3B is substantially identical to FIG. 3A, except that there is a difference in a measuring location of voltage between the first voltage measurer 210 and the second voltage measurer 220.

That is, referring to FIG. 3B, the first voltage measurer 210 measures a voltage (Vcell_2) applied on both ends of the referenced battery cell 502 included in the battery module 201, and the second voltage measurer 220 measures a voltage (V2) between one end of the battery cell 502 that is farther from the busbar 701 and one end of the battery module 202 that is connected to the busbar 701. In this case, the second voltage (V2) measured by the second voltage measurer 220 is V2=Vcell_2+(R1+R2+R10)*i.

The voltage calculator 230 calculates a voltage (Vbusbar) across two ends of the busbar based on the first voltage (Vcell_2) and the second voltage (V2). In this case, the voltage (Vbusbar) calculated by the voltage calculator 230 is Vbusbar=V2−Vcell_2=(R1+R2+R10)*i.

The status determiner 120 compares the voltage (Vbusbar) across two ends of the busbar with a predetermined threshold voltage (Vth) to determine whether connection status is a risk status.

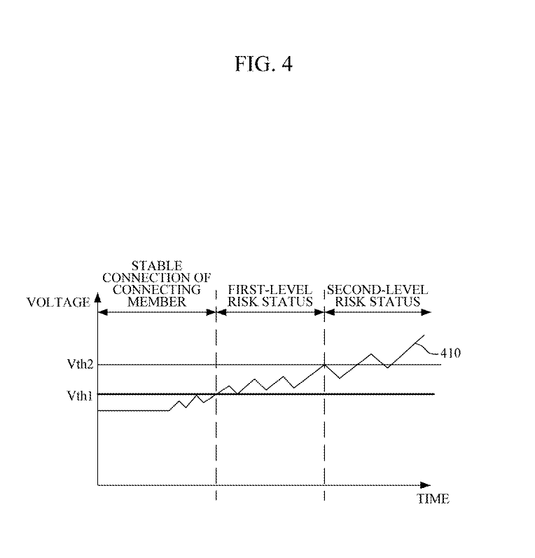

FIG. 4 is a diagram illustrating an example of a criterion for determining connection status of a busbar based on a voltage across two ends of a busbar. In FIG. 4, a risk status is divided into two levels, but is not limited thereto, and may be integrated into one level or divided into three or more levels according to performance and usage of a system, and depending on embodiments.

Referring to FIG. 4, in response to a voltage 410 across two ends of the busbar, e.g. the Vbusbar of either or both of FIGS. 3A and 3B, being at a threshold voltage of Vth1 or higher, the status determiner 120 determines that connection status is a first-level risk status. In response to the voltage 410 across two ends of the busbar being at a threshold voltage of Vth2 or higher, the status determiner 120 determines that connection status is a second-level risk status. In this case, a degree of risk status increases from the first-level risk status to the second-level risk status as looseness of the connecting member increases.

As illustrated in FIG. 4, once the status determiner 120 determines that connection status is a risk status (first-level risk status or second-level risk status), the determination made by the status determiner 120 that connection status is a risk status may not be changed even when the voltage 410 applied on both ends of the busbar later becomes lower than the threshold voltage (Vth1 or Vth2). However, the present disclosure is not limited thereto, and even when the status determiner 120 determines that connection status is a risk status (first-level risk status or second-level risk status), the determination made by the status determiner 120 that connection status is a risk status may be changed if the voltage 410 is maintained to be lower than the threshold voltage (Vth1 or Vth2) for a specific period of time, for example.

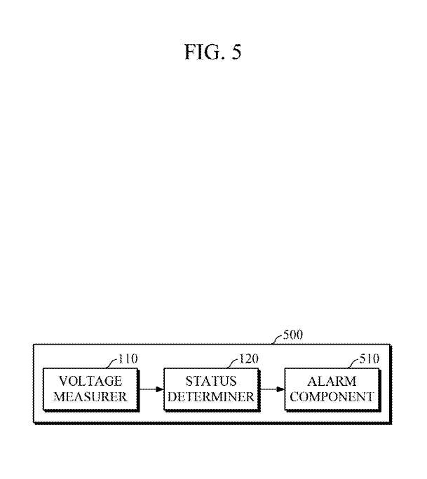

FIG. 5 is a diagram illustrating an example of an apparatus for determining connection status of a busbar

Referring to FIGS. 5, an apparatus 500 for determining connection status of a busbar may further include an alarm component 510 in addition to the apparatus 100 for determining connection status of a busbar illustrated in FIG. 1, as an example. Once the status determiner 120 determines that connection status of a busbar is a risk status, the alarm component 510 may output an alarm by using an acoustic method (e.g., speaker, etc.), a visual method (e.g., LED, lamp, etc.), or a tactile method (e.g., vibration, other haptic feedback, etc.), or any combination thereof.

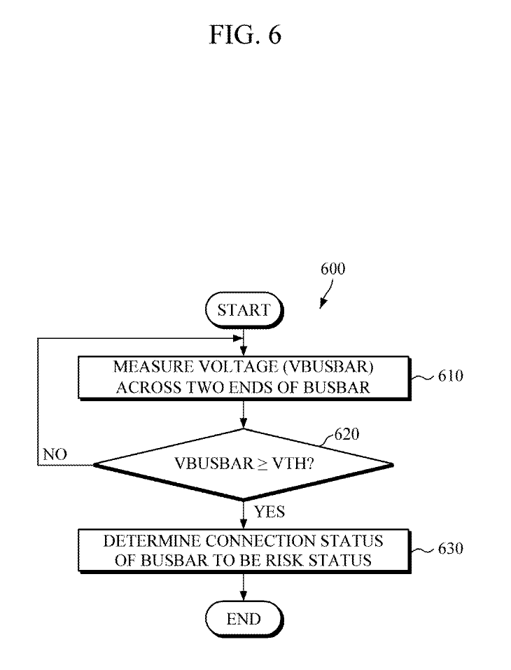

FIG. 6 is a flowchart illustrating an example of a method of determining connection status of a busbar.Referring to FIG. 6, a method 600 of determining connection status of a busbar includes measuring a voltage (Vbusbar) across ends of a busbar in 610. For example, the apparatus 100 for determining connection status of the busbar measures a voltage (Vbusbar) across two ends of the busbar connecting two battery modules (a first battery module and a second battery module) in series.

The voltage (Vbusbar) across the ends of the busbar may vary according to an interval resistance of the busbar, an internal resistance of connecting members (a first connecting member and a second connecting member), and a virtual resistance generated between the busbar and the connecting members according to a degree of connection of the busbar and the connecting members.

In an embodiment, the apparatus 100 for determining connection status of the busbar directly measures the voltage (Vbusbar) across two ends of the busbar by measuring a voltage between one end the first battery module that is connected to the busbar and an end of the second battery module that is connected to the busbar.

In another embodiment, the apparatus 100 for determining connection status of the busbar indirectly measures a voltage across ends of a busbar by measuring a first voltage across two ends of a first battery cell that is connected to the busbar among a plurality of battery cells and a second voltage between one end of the first battery cell that is farther from the busbar and one end of the second battery module that is connected to the busbar, and calculating a voltage across two ends of the busbar according to the measured first voltage and second voltage.

The voltage (Vbusbar) across such ends of the busbar is compared to a predetermined threshold voltage (Vth) to determine whether the voltage (Vbusbar) is greater than the predetermined threshold voltage (Vth) in 620.

In response to the voltage (Vbusbar) being determined to meet, e.g., be greater than the threshold voltage (Vth), a connection status of the busbar is determined to be a risk status in 630. If the voltage (Vbusbar) is determined to not meet, e.g., is equal or less than the threshold voltage, then operation 610 is repeated. For example, operation 610 must be implemented in periodic intervals until a risk status is determined.

By tightening the first connecting member and the second connecting member to firmly connect the first battery module with the busbar and the second battery module with the busbar, a first virtual resistance generated between the busbar and the first connecting member and the busbar should be zero or almost zero, and a second virtual resistance generated between the busbar and the second connecting member and the busbar should be zero or almost zero. By contrast, in the case where the connection of the first battery module with the busbar or the connection of the second battery module with the busbar becomes loose or disconnected due to loosening of the first connecting member and/or the second connecting member, the first virtual resistance or the second virtual resistance will be hound to have increased.

Accordingly, the apparatus 100 for determining connection status of the busbar may determine connection status of the busbar with the first battery module and the second battery module based on the measured voltage across two ends of the busbar. For example, the apparatus 100 for determining connection status of the busbar compares the voltage across two ends of the busbar with a predetermined threshold voltage. In response to the voltage across two ends of the busbar being greater than the predetermined threshold voltage, the apparatus 100 determines that that there is a risk of disconnection of the first connecting member or the second connecting member, i.e., connection status of the busbar is unstable (hereinafter referred to as a “risk status”).

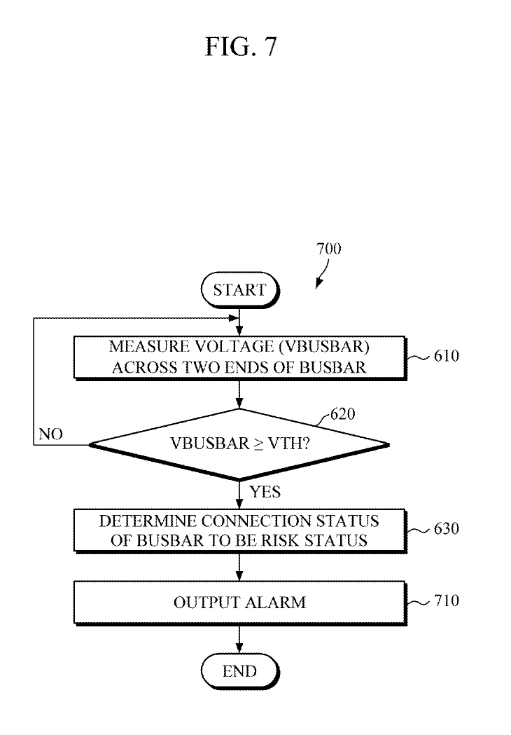

FIG. 7 is a flowchart illustrating another example of a method of determining connection status of a busbar. Referring to FIGS. 6 and 7, in addition to the method 610 of determining connection status of a busbar illustrated in FIG. 6, a method 700 of determining connection status of a busbar further includes outputting an alarm in 710 by using an acoustic method (e.g., speaker, etc.), a visual method (e.g., LED, lamp, display, etc.), or a tactile method (e.g., vibration, haptic feedback etc.), or any combination thereof, in response to a determination that connection status of the busbar is a risk status.

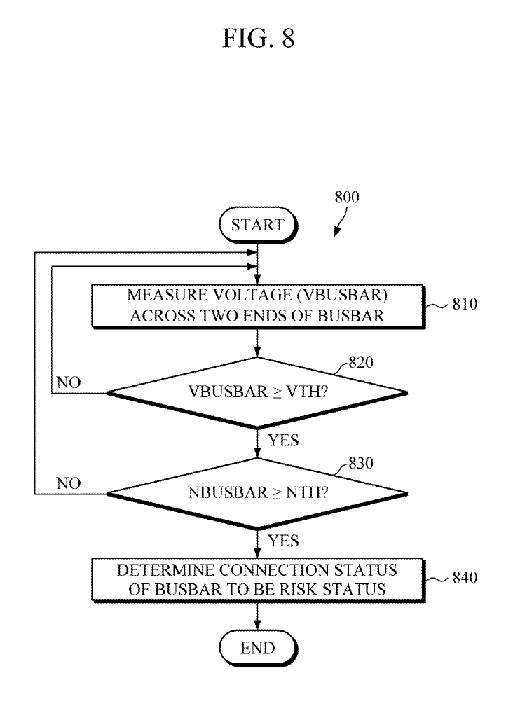

FIG. 8 is a flowchart illustrating another example of a method of determining connection status of a busbar. Referring to FIG. 8, a method 800 of determining connection status of a busbar includes directly or indirectly measuring voltage (Vbusbar) across two ends of the busbar in 810. The measured voltage (Vbusbar) is compared with the predetermined threshold voltage (Vth) to determine whether the voltage (Vbusbar) is greater than the predetermined threshold voltage (Vth) in 820. In response to the voltage (Vbusbar) being determined to be greater than the predetermined threshold voltage (Vth), a set number of times (Nbusbar) the voltage (Vbusbar) is greater than the predetermined threshold voltage (Vth) is determined and whether the number (Nbusbar) is above a predetermine threshold value (Nth) in 830.

Upon determination in 830, in response to the number (Nbusbar) being greater than the predetermined threshold value (Nth), connection status of the busbar is determined to be a risk status in 840.

The apparatuses, units, modules, devices, and other components illustrated in FIGS. 1-3C and 5 that perform the operations described herein with respect to FIGS. 4 and 6-8 are hardware components. Examples of hardware components include controllers, sensors, generators, drivers, memories, comparators, arithmetic logic units, adders, subtractors, multipliers, dividers, integrators, and any other electronic components known to one of ordinary skill in the art. In one example, the hardware components are computing hardware, for example, by one or more processors or computers. A processor or computer is one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices known to one of ordinary skill in the art that is capable of responding to and executing instructions in a defined manner to achieve a desired result. In one example, a processor or computer includes, or is connected to, one or more memories storing instructions or software that are executed by the processor or computer. Hardware components implemented by a processor or computer execute instructions or software, such as an operating system (OS) and one or more software applications that run on the OS, to perform the operations described herein with respect to FIGS. *. The hardware components also access, manipulate, process, create, and store data in response to execution of the instructions or software. For simplicity, the singular term “processor” or “computer” may be used in the description of the examples described herein, but in other examples multiple processors or computers are used, or a processor or computer includes multiple processing elements, or multiple types of processing elements, or both. In one example, a hardware component includes multiple processors, and in another example, a hardware component includes a processor and a controller. A hardware component has any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 4 and 6-8 that perform the operations described herein with respect to FIGS. 4 and 6-8 are performed by a processor or a computer as described above executing instructions or software to perform the operations described herein.

Instructions or software to control a processor or computer to implement the hardware components and perform the methods as described above are written as computer programs, code segments, instructions or any combination thereof, for individually or collectively instructing or configuring the processor or computer to operate as a machine or special-purpose computer to perform the operations performed by the hardware components and the methods as described above. In one example, the instructions or software include machine code that is directly executed by the processor or computer, such as machine code produced by a compiler. In another example, the instructions or software include higher-level code that is executed by the processor or computer using an interpreter. Programmers of ordinary skill in the art can readily write the instructions or software based on the block diagrams and the flow charts illustrated in the drawings and the corresponding descriptions in the specification, which disclose algorithms for performing the operations performed by the hardware components and the methods as described above.

The instructions or software to control a processor or computer to implement the hardware components and perform the methods as described above, and any associated data, data files, and data structures, are recorded, stored, or fixed in or on one or more non-transitory computer-readable storage media. Examples of a non-transitory computer-readable storage medium include read-only memory (ROM), random-access memory (RAM), flash memory, CD-ROMs, CD-Rs, CD+Rs, CD-RWs, CD+RWs, DVD-ROMs, DVD-Rs, DVD+Rs, DVD-RWs, DVD+RWs, DVD-RAMS, BD-ROMs, BD-Rs, BD-R LTHs, BD-REs, magnetic tapes, floppy disks, magneto-optical data storage devices, optical data storage devices, hard disks, solid-state disks, and any device known to one of ordinary skill in the art that is capable of storing the instructions or software and any associated data, data files, and data structures in a non-transitory manner and providing the instructions or software and any associated data, data files, and data structures to a processor or computer so that the processor or computer can execute the instructions. In one example, the instructions or software and any associated data, data files, and data structures are distributed over network-coupled computer systems so that the instructions and software and any associated data, data files, and data structures are stored, accessed, and executed in a distributed fashion by the processor or computer.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. An apparatus for determining connections status of a busbar, the apparatus comprising:
a voltage measurer configured to measure a voltage across two ends of the busbar used to connect a first battery module and a second battery module in series; and
a status determiner configured to determine connection status of the busbar according to the voltage.

2. The apparatus of claim 1, wherein the voltage measurer is configured to measure the voltage by measuring the voltage between one end of the first battery module connected to the busbar and one end of the second battery module connected to the busbar.

3. The apparatus of claim 1, wherein the voltage measurer is configured to:
measure a first voltage across two ends of a battery cell of the first battery module connected to the busbar;
measure a second voltage between one end of the second battery module connected to the busbar and one end of the first battery cell farther from the busbar than another end of the first battery cell; and
calculate the voltage across two ends of the busbar based on the measured first voltage and the measured second voltage.

4. The apparatus of claim 1, wherein the status determiner is configured to:
compare the voltage across two ends of the busbar with a threshold voltage, and
determine that connection status of the busbar is a risk status in response to the comparing indicating that the voltage across two ends of the busbar meets the threshold voltage.

5. The apparatus of claim 4, wherein in response to the voltage accross two ends of the busbar being greater than the predetermined threshold voltage, the status determiner is configured to determine whether the voltage across two ends of the busbar is determined to meet the threshold voltage a number of times that meets a second threshold value, and in response to the number of times meeting the second threshold value, the status determiner is configured to determine the connection status of the busbar to be a risk status.

6. The apparatus of claim 1, further comprising:
an alarm component configured to output an acoustic alarm, a visual alarm, or a tactile alarm, or any combination thereof, in response to the determiner determining that the connection status of the busbar as in a risk status.

7. A method of determining connection status of a busbar, the method comprising:
measuring a voltage across two ends of the busbar connecting a first battery module and a second battery module in series; and
determining a connection status of the busbar based on the voltage.

8. The method of claim 7, wherein the measuring of the voltage comprises:
measuring the voltage across two ends of the busbar by measuring the voltage between one end of the first battery module connected to the busbar and one end of the second battery module connected to the busbar.

9. The method of claim 7, wherein the measuring of the voltage comprises:
measuring a first voltage across two ends of a battery cell, of the first battery module, connected to the busbar;
measuring a second voltage between one end of the second battery module connected to the busbar one end of the first battery cell distal to the busbar; and
calculating the voltage across two ends of the busbar according to the measured first voltage and the measured second voltage.

10. The method of claim 7, wherein determining of the connection status of the busbar comprises:
comparing the voltage across two ends of the busbar with a predetermined threshold voltage; and
determining that connection status of the busbar is a risk status in response to the comparing indicating that the voltage across two ends of the busbar meets the threshold voltage.

11. The method of claim 10, wherein in response to the voltage across two ends of the busbar being meeting the threshold voltage, the determining of the connection status of the busbar further comprises:
comparing a number of times the voltage across two ends of the busbar is greater than the threshold voltage with a second threshold value; and
in response to the number of times the voltage applied on both ends of the busbar is greater than the threshold voltage being above the second threshold value, determining the connection status of the busbar to be the risk status.

12. The method of claim 7, further comprising outputting an acoustic alarm, a visual alarm, or a tactile alarm, or any combination thereof, in response to the risk status.
